(19) United States
(12) Patent Application Publication
(10) Pub. No.: US 2023/0268180 A1
(43) Pub. Date: Aug. 24, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventors: Xiangyu WANG, Hefei City (CN); Shuhao ZHANG, Hefei City (CN); Ning LI, Hefei City (CN)

(21) Appl. No.: 17/804,942

(22) Filed: Jun. 1, 2022

(30) Foreign Application Priority Data
Feb. 24, 2022 (CN) 202210172470.0

(51) Int. Cl. H01L 21/28; H01L 29/40; H01L 29/49; H01L 21/8238

(52) U.S. Cl. CPC H01L 21/28035; H01L 29/401; H01L 29/4916; H01L 21/823871; H01L 21/28123; H01L 27/092

(57) ABSTRACT

The present disclosure provides a semiconductor structure and a manufacturing method thereof. The manufacturing method of a semiconductor structure includes: providing an initial semiconductor structure, where the initial semiconductor structure includes a substrate and a polycrystalline silicon layer; forming a first mask layer on the initial semiconductor structure, where the first mask layer has a first ion implantation window, and the first ion implantation window defines a position of a gate electrode of a first transistor; and performing a first ion implantation process to perform work function adjustment on the gate electrode of the first transistor through the first ion implantation window, to form a semiconductor structure.

### CROSS-REFERENCE TO RELATED APPLICATION

This disclosure claims the priority of Chinese Patent Application No. 202210172470.0, submitted to the Chinese Intellectual Property Office on Feb. 24, 2022, the disclosure of which is incorporated herein in its entirety by reference.

### TECHNICAL FIELD

The present disclosure relates to the technical field of semiconductors, and specifically to a semiconductor structure and a manufacturing method thereof.

### BACKGROUND

With the rapid development of very large scale integration technologies, a size of a metal oxide semiconductor (MOS) transistor is constantly decreased, which usually involves the reduction of a channel length of the MOS transistor and the thinning of a thickness of a gate oxide layer, to obtain a faster device speed.

MOS transistors can be divided into P-type MOS transistors and N-type MOS transistors according to types of conductive channels. Since threshold voltages of an NMOS and a PMOS are different, the NMOS and the PMOS need to use different work function adjusting layers.

It should be noted that the information disclosed above is merely intended to facilitate a better understanding of the background of the present disclosure, and therefore may include information that does not constitute the prior art known to those of ordinary skill in the art.

### SUMMARY

According to an aspect of embodiments of the present disclosure, a manufacturing method of a semiconductor structure is provided, including:

providing an initial semiconductor structure, where the initial semiconductor structure includes a substrate and a polycrystalline silicon layer;

forming a first mask layer on the initial semiconductor structure, where the first mask layer has a first ion implantation window, and the first ion implantation window defines a position of a gate electrode of a first transistor; and

performing a first ion implantation process to perform work function adjustment on the gate electrode of the first transistor through the first ion implantation window, to form a semiconductor structure.

According to another aspect of the embodiments of the present disclosure, a semiconductor structure is provided, including a substrate and a polycrystalline silicon layer, where the polycrystalline silicon layer is processed by the above-mentioned manufacturing method, to obtain the semiconductor structure.

### BRIEF DESCRIPTION OF THE DRAWINGS

The accompanying drawings incorporated into the specification and constituting part is of the specification illustrate the embodiments of the present disclosure, and serve, together with the specification, to explain the principles of the present disclosure. Apparently, the drawings in the following description show merely some embodiments of the present disclosure, and those of ordinary skill in the art may still derive other drawings from these drawings without creative efforts. In the drawings:

FIG. 1 is a schematic diagram of an adjustment relationship between an on-state current and an off-state current according to an embodiment of the present disclosure;

FIG. 2 is a schematic diagram of an adjustment relationship between a threshold voltage and a drain-source current according to an embodiment of the present disclosure;

FIG. 3 is a schematic diagram of an adjustment relationship between a threshold voltage and an off-state current according to an embodiment of the present disclosure;

FIG. 4 is a flowchart of a manufacturing method of a semiconductor structure according to an embodiment of the present disclosure;

FIG. 5 is a schematic diagram of a semiconductor structure according to an embodiment of the present disclosure;

FIG. 6 is a flowchart of a manufacturing method of a semiconductor structure according to another embodiment of the present disclosure;

FIG. 7 is a flowchart of a manufacturing method of a semiconductor structure according to still another embodiment of the present disclosure;

FIG. 8 is a schematic diagram of comparing EOTs before and after optimization of a semiconductor structure according to an embodiment of the present disclosure; and

FIG. 9 is a schematic diagram of comparing VTs/IDSs/IOFFs before and after optimization of a semiconductor structure according to an embodiment of the present disclosure.

### DETAILED DESCRIPTION

The exemplary implementations are described more comprehensively below with reference to the accompanying drawings. However, the exemplary implementations can be implemented in various forms and should not be construed as being limited to examples described herein. On the contrary, these implementations are provided such is that the present disclosure is more comprehensive and complete, and fully conveys the concept of the exemplary implementations to those skilled in the art.

The described features, structures, or characteristics may be incorporated into one or more embodiments in any suitable manner. The following description offers many specific details in order for a full understanding of the embodiments of the present disclosure. However, those skilled in the art will be aware that the technical solutions of the present disclosure may be practiced with one or more of the specific details omitted, or other methods, components, apparatuses, steps, and the like may be used. In other cases, well-known methods, apparatuses, implementations, or operations are not shown or described in detail to avoid obscuring aspects of the present disclosure.

The block diagrams shown in the drawings are merely functional entities, which do not necessarily correspond to physically independent entities. These functional entities may be implemented in the form of software, or implemented in one or more hardware modules or integrated circuits, or implemented in different networks and/or processor apparatuses and/or microcontroller apparatuses.

The flowcharts shown in the accompanying drawings are only exemplary illustrations, and it is not mandatory to include all content and operations/steps, or perform the operations/steps in the order described. For example, some operations/steps can also be decomposed, while some operations/steps can be merged or partially merged. Therefore, an actual execution order may change based on an actual situation.

Due to the impact of various factors, a channel of a MOS transistor actually cannot be completely pinched off during operation, that is, a drain current ID of the MOS transistor cannot reach a true 0 state. Therefore, in practical application, when the drain current of the MOS transistor is very close to 0, it is considered that a voltage difference between the gate electrode and the source electrode of the transistor is called a pinch-off voltage of the MOS transistor, and a drain current generated at this time is called an off-state current Ioff of the transistor. Accordingly, for an NMOS, a drain current generated when a drive voltage VGS is greater than 0 and the VGS is a multiple (not less than 1) of a pinch off voltage is called an on-state current Ion; for a PMOS, a drain current generated when the VGS is less than 0 and an absolute value of the VGS is a multiple (not less than 1) of a pinch off voltage is called an on-state current Ion. The off-state current Ioff of the transistor is actually a leakage current of the transistor. A smaller off-state current of the transistor indicates smaller power consumption of the transistor. Therefore, for a MOS transistor, a larger ratio of the on-state current to the off-state current, that is, Ion/Ioff indicates that the smaller power consumption of the transistor and the faster speed. Therefore, the ratio of the on-state current to the off-state current of the transistor, that is, Ion/Ioff needs to be increased.

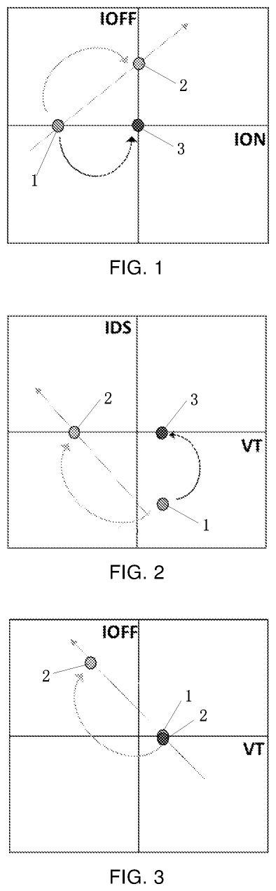

As shown in FIG. 1 to FIG. 3, point 1 indicates electrical performance of a semiconductor device without adjustment. The horizontal axis represents the on-state current ION, and the vertical axis represents the off-state current IOFF. Point 2 indicates electrical performance of a new semiconductor device formed through a traditional adjustment method, which is mainly implemented by adjusting lightly doped drain (LDD), halo (high doping at a source end of a channel region), channel concentration, and the like. As can be seen, a leakage current IOFF (off-state current) is also increased while ION (on-state current) is increased, and a threshold voltage VT is reduced. This is because these adjustments are performed inside or near a channel and synchronously affect ION/IOFF/VT, and cannot keep VT/IOFF unchanged while increasing ION. When IOFF is increased, it indicates that power consumption is increased. When VT is reduced, it indicates that a turn-on voltage of a device is reduced and it is easy to turn on the device by mistake.

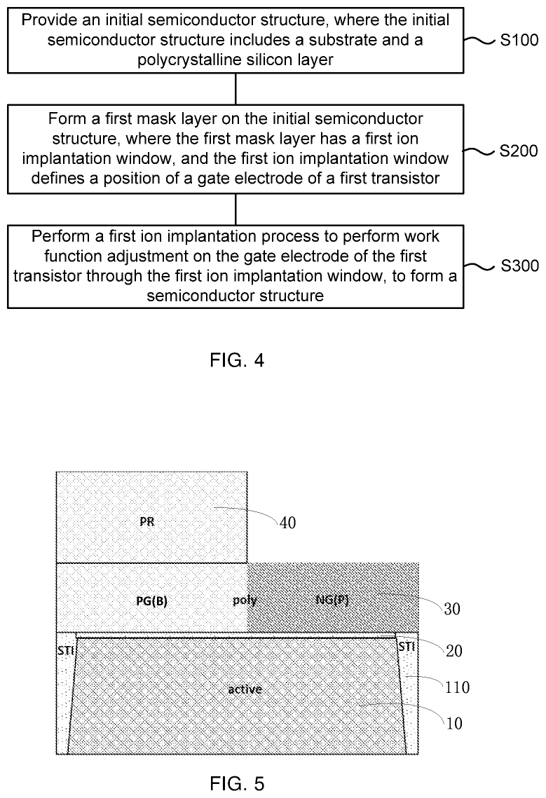

An embodiment of the present disclosure first provides a manufacturing method of a semiconductor structure. As shown in FIG. 4, the manufacturing method includes:

Step S100: Provide an initial semiconductor structure, where the initial semiconductor structure includes a substrate and a polycrystalline silicon layer.

Step S200: Form a first mask layer on the initial semiconductor structure, where the first mask layer has a first ion implantation window, and the first ion implantation window defines a position of a gate electrode of a first transistor.

Step S300: Perform a first ion implantation process to perform work function adjustment on the gate electrode of the first transistor through the first ion implantation window, to form a semiconductor structure.

In the manufacturing method of a semiconductor structure provided by the present disclosure, the first mask layer with the first ion implantation window is formed on the initial semiconductor structure, the first ion implantation window defines the position of the gate electrode of the first transistor, and then work function adjustment is performed on the gate electrode of the first transistor through the first ion implantation window, to form the semiconductor structure. This implements work function adjustment on the gate electrode of the transistor.

The steps of the manufacturing method of a semiconductor structure provided in the present disclosure are described in detail below.

In step S100, the initial semiconductor structure is provided, where the initial semiconductor structure includes a substrate and a polycrystalline silicon layer.

Specifically, an initial semiconductor structure is provided, and as shown in FIG. 5, the semiconductor structure includes a substrate 10 and a polycrystalline silicon layer 30. The substrate 10 is a semiconductor material, including, but not limited to, a monocrystalline silicon substrate, a polycrystalline silicon substrate, a gallium nitride substrate, or a sapphire substrate. In addition, when the semiconductor substrate is a monocrystalline substrate or a polycrystalline substrate, the semiconductor substrate may also be an intrinsic silicon substrate or a lightly doped silicon substrate. Further, the semiconductor substrate may be an N-type polycrystalline silicon substrate or a P-type polycrystalline silicon substrate.

As shown in FIG. 5, a shallow trench isolation (STI) structure 110 is formed on the substrate 10. The semiconductor substrate can be isolated by the shallow trench isolation technology, and a shallow trench isolation trench is formed on the semiconductor substrate. The depth of the shallow trench isolation trench may be, for example, 20 nm to 40 nm. A shallow trench isolation structure is formed in the etched shallow trench isolation trench through chemical vapor deposition (CVD), physical vapor deposition (PVD), or other deposition techniques. Multiple active regions are isolated by the shallow trench isolation structure, where a material of the shallow trench isolation structure may include insulating materials such as silicon nitride or silicon oxide. As an example, a source electrode, a drain electrode, and a channel region (not shown) of a MOS device are formed in the active region. The MOS device further includes a gate electrode. The source electrode and the drain electrode are respectively located on opposite sides of the gate electrode.

As shown in FIG. 5, an insulating oxide layer 20 is further provided between the polycrystalline silicon layer 30 and the substrate 10, and the insulating oxide layer 20 is configured to implement electrical insulation between the polycrystalline silicon layer 30 and the substrate 10. A material of the insulating oxide layer 20 may be a material with a high dielectric constant, for example, silicon oxide, silicon oxynitride, silicon nitride, or hafnium oxide, or other suitable insulating substances (e.g., organic polymer compounds), or a combination of the above materials. The insulating oxide layer 20 is formed through, for example, physical vapor deposition, chemical vapor deposition, spin coating, or a combination thereof.

The polycrystalline silicon layer 30 may serve as the gate electrode of the semiconductor device. In the early days, metal aluminum is widely used as a preferred gate material for MOS, and the MOS manufacturing process starts from the definition and doping of a source region and a drain region. Then, a gate cover is used to define a gate oxide region, thereby forming an aluminum metal gate. A major disadvantage of this manufacturing process is that parasitic overlap input capacitors Cgd and Cgs are created if a gate mask is misaligned. Since the capacitor is a feedback capacitor, the capacitor Cgd is more harmful. A switching speed of the transistor is reduced due to the Miller capacitance.

A method for addressing the gate mask misalignment is the so-called “self-aligned gate process”. In this process, a gate region is first created and then ion implantation is performed to create a drain region and a source region. The thin gate oxide layer under the gate acts as a cover for the doping process, preventing further doping under the gate region (channel). Thus, this process ensures self-alignment of the gate electrode with respect to the source region and the drain region. Therefore, the source region and the drain region do not extend below the gate electrode. The doping process of the drain is region and the source region requires an ultra-high temperature annealing method (usually >8,000° C.). If aluminum is used as a sprue material, aluminum melts at such a high temperature. This is because the melting point of aluminum is about 660° C. However, if polycrystalline silicon is used as a sprue material, polycrystalline silicon does not melt. Therefore, a self-alignment process of the polycrystalline silicon gate is possible. However, this is impossible in the case of an aluminum gate, which results in high Cgd and Cgs. Therefore, polycrystalline silicon is mostly used as a gate material in current semiconductor devices.

The source electrode, the drain electrode, and the gate electrode are respectively connected to a test end through contact plugs and conductive wires, receive test voltages and currents, and output working voltages and currents.

A word line trench (not shown in the figure) can be formed through anisotropic etching in a region between two adjacent shallow trench isolation structures on the substrate 10, and a metal word line can be formed in the word line trench through chemical vapor deposition, physical vapor deposition, or other methods. Conductive materials for forming the word lines include one or a combination of tungsten, titanium, nickel, aluminum, titanium oxide, and titanium nitride. Those skilled in the art may also select other conductive materials, which are not limited in the present disclosure.

In step S200, the first mask layer is formed on the initial semiconductor structure, where the first mask layer has the first ion implantation window, and the first ion implantation window defines the position of the gate electrode of the first transistor.

Specifically, as shown in FIG. 5, a first mask material layer is deposited on the initial semiconductor structure. The first mask material layer is, for example, photoresist. Then, a patterned first mask layer 40 is formed by exposing and developing the photoresist, so that the patterned first mask layer 40 has the first ion implantation window. The first ion implantation window defines the position of the gate electrode of the first transistor. The photoresist may be positive photoresist or negative photoresist.

In step S300, the first ion implantation process is performed to perform work function adjustment on the gate electrode of the first transistor through the first ion implantation is window, to form the semiconductor structure.

Specifically, polycrystalline silicon that is not doped has a very high resistivity, which is about 108 Ω/cm. Therefore, a doping method of polycrystalline silicon reduces the resistance. Besides, to adjust the threshold voltage of the semiconductor device, ion implantation of different doping types is performed on the polycrystalline silicon, to reduce a work function difference between the metal gate electrode and the semiconductor substrate.

In an embodiment of the present disclosure, as shown in FIG. 5, an N-type polycrystalline silicon layer is formed by performing ion implantation on the polycrystalline silicon layer 30 according to the first ion implantation window, to serve as the gate electrode of the N-type transistor. Doped particles of ion implantation of the polycrystalline silicon layer 30 are, for example, at least one of phosphorus (P) or arsenic (As), and doping concentration may be 1,013 atoms/cm² to 1,016 atoms/cm². A resistance per unit area of the polycrystalline silicon gate can be further adjusted by adjusting the doping concentration. Higher doping concentration indicates a lower resistance per unit area of the polycrystalline silicon gate. The photoresist does not cover the gate region of the N-type transistor, that is, the N-type polycrystalline silicon layer (N-POLY) is open. Therefore, P/As atoms are precipitated when the photoresist is washed subsequently, resulting in the depletion effect of the polycrystalline silicon gate (When the doping concentration of the polycrystalline silicon is limited, there is a voltage drop thereon. Therefore, there is an electric field inside the polycrystalline silicon gate, so that electrons/holes near the surface of the insulating oxide layer are easily attracted to a side of the polycrystalline silicon gate by the electric field. As a result, a depletion layer appears near the surface of the insulating oxide layer, which increases the equivalent oxide thickness (EOT) of the semiconductor device).

In another embodiment of the present disclosure, ion implantation is performed on the polycrystalline silicon layer 30 according to the first ion implantation window, to form a P-type polycrystalline silicon layer, to serve as a gate electrode of the P-type transistor. Doped particles of ion implantation of the polycrystalline silicon layer 30 are, for example, is boron (B), and doping concentration may be 1,013 atoms/cm² to 1,016 atoms/cm². A resistance per unit area of the polycrystalline silicon gate can be further adjusted by adjusting the doping concentration. Higher doping concentration indicates a lower resistance per unit area of the polycrystalline silicon gate. The photoresist does not cover the gate region of the P-type transistor, that is, the P-type polycrystalline silicon layer (P-POLY) is open. Therefore, B atoms are precipitated when the photoresist is washed subsequently, resulting in the depletion effect of the polycrystalline silicon gate.

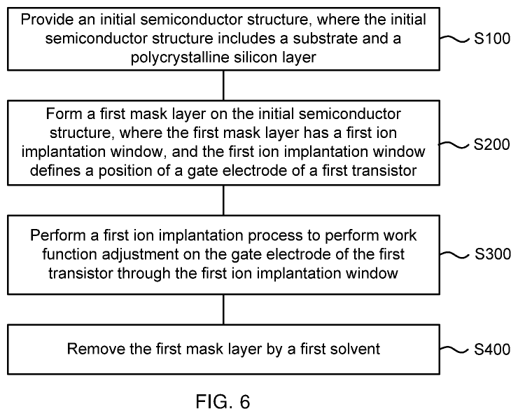

Specifically, after the first ion implantation process is performed, as shown in FIG. 6, the manufacturing method further includes step S400: Remove the first mask layer by a first solvent, to form the semiconductor structure.

After the first ion implantation process is performed on the polycrystalline silicon layer 30, the photoresist (the first mask layer 40) on the initial semiconductor structure is washed with the first solvent, to form the semiconductor structure. The first solvent (APM solvent) is a hybrid aqueous solution of ammonia water (NH₄OH) and hydrogen peroxide (H₂O₂).

A concentration of ammonia water falls within a first range, a concentration of hydrogen peroxide falls within a second range, a concentration of water falls within a third range, the third range is greater than the second range, and the second range is greater than the first range. By improving a ratio of the above solution, precipitation of implanted ions in polycrystalline silicon can be reduced, the depletion effect of polycrystalline silicon gates can be reduced, the equivalent oxide thickness can be reduced, the ion precipitation loss of polycrystalline silicon can be reduced, and the resistance value of polycrystalline silicon can also be reduced. By shortening the process time and improving the ratio of the above solution, the thickness loss of the polycrystalline silicon layer can be reduced by about 1.5 nm compared with the conventional process, that is, the thickness of the polycrystalline silicon layer is increased by 1.5 nm compared with the conventional process. Because the thickness of the polycrystalline silicon layer is inversely proportional to the block resistance value (p(resistivity)=R*a(width)*t(thickness)/b(length)), the performance of the device is optimized.

In the first solvent, a ratio of the concentration of water to a sum of the concentration of ammonia water and the concentration of hydrogen peroxide is greater than 5:1. Preferably, a mole ratio of ammonia water (NH₄OH) to hydrogen peroxide (H₂O₂) to water (H₂O) is 1:(1-10):(50-100), such as 1:1:50, 1:5:70, or 1:10:100, which are not listed herein in the present disclosure.

Specifically, the removing the first mask layer by a first solvent includes: removing the first mask layer by both the first solvent and a second solvent. The second solvent (SPM solvent) is a hybrid aqueous solution of sulfuric acid (H₂SO₄) and hydrogen peroxide (H₂O₂). The first solvent may be mixed with the second solvent to wash the photoresist (the first mask layer) on the initial semiconductor structure.

In an embodiment of the present disclosure, the washing the photoresist on the initial semiconductor structure with the first solvent (and the second solvent) includes: placing the initial semiconductor structure in a spin coating device, and absorbing the back side of the initial semiconductor structure away from the photoresist with a vacuum chuck; spraying the first solvent (and the second solvent) on the photoresist; rotating the initial semiconductor structure, so that the first solvent covers the surface of the photoresist and is thrown out; and stopping rotating the initial semiconductor structure and taking the initial semiconductor structure out of the spin coating device.

In another embodiment of the present disclosure, the washing the photoresist on the initial semiconductor structure with the first solvent (and the second solvent) includes: spraying the first solvent (and the second solvent) on the surface of the photoresist; and washing the photoresist through ultrasonic waves.

In another embodiment of the present disclosure, the washing the photoresist on the initial semiconductor structure with the first solvent (and the second solvent) further includes: removing a part of the photoresist through plasma ashing and/or wet cleaning, and washing the remaining photoresist by the first solvent and the second solvent.

The photoresist is washed by the first solvent (and the second solvent), and the photoresist is washed for multiple times, so as to improve the cleaning effect.

A time in which the photoresist is washed by the first solvent (and the second solvent) is 30 s to 150 s, such as 30 s, 50 s, 70 s, 100 s, 130 s, or 150 s, which are not listed herein in the present disclosure. Certainly, the time for cleaning the photoresist may also be less than 30 s or greater than 150 s, which is not limited in the present disclosure. By controlling the cleaning time and reducing the time of reaction between polycrystalline silicon and the first solvent (the second solvent), the reaction between doped ions, B ions, and/or AS/P ions in polycrystalline silicon and the first solvent (the second solvent) can be reduced. Therefore, the depletion effect of the polycrystalline silicon gate can be reduced, so that the EOT of the device with the semiconductor structure is reduced and the ION is increased.

The photoresist is cleaned by the first solvent (and the second solvent), where a temperature for cleaning the photoresist is 25° C. to 30° C., such as 25° C., 26° C., 27° C., 28° C., 29° C., or 30° C. ° C., which are not listed herein in the present disclosure. Certainly, the temperature for cleaning the photoresist may also be less than 25° C. or greater than 30° C., which is not limited in the present disclosure.

By reducing the temperature for cleaning the photoresist, reaction of implanted ions in the polycrystalline silicon layer can be reduced, so that a depletion region can be reduced, the EOT of the device with the semiconductor structure can be reduced, and the ION can be increased. As can be seen from sensitivity of EOT and VT/IDS/IOFF, since the EOT is highly sensitive to a current while the VT and the IOFF are insensitive, slightly reducing the precipitation of B or P actually increases the ION, which implements more precise control than ion implantation improvement.

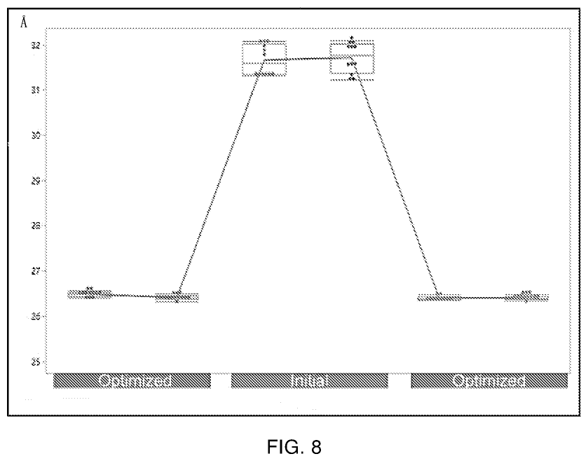

The present disclosure improves the performance of the ION by controlling the method of cleaning after work function adjustment of the gate electrode. First, an electrical thickness of the oxide layer is reduced mainly by reducing the precipitation of P and B in the polycrystalline silicon layer, so as to increase the ION without affecting the VT and the IOFF. As shown in FIG. 8, “initial” on the abscissa represents an optimized wafer, and “optimized” represents a wafer optimized using the manufacturing method of the present disclosure. An ordinate is an EOT value of an NMOS, and the unit is Å (1 e-10 m). It can is be seen that the EOT of the NMOS before optimization is 31 Å to 32 Å, and the EOT of the NMOS after optimization is 26 Å to 27 Å. Therefore, the EOT of the wafer after optimization is obviously reduced.

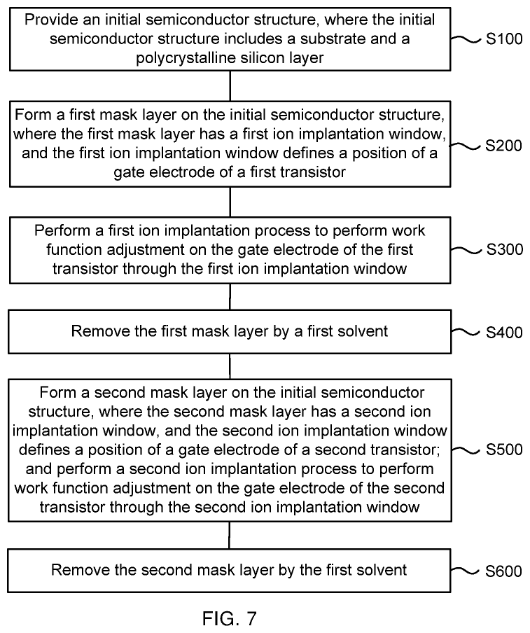

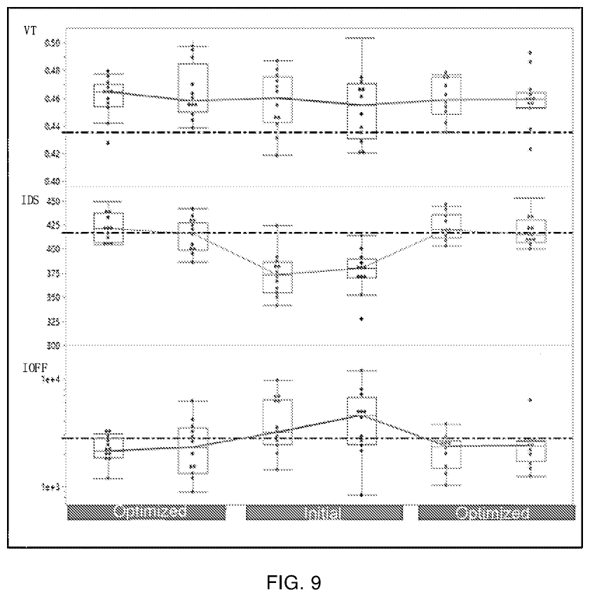

Secondly, the present disclosure reduces the poly loss by adjusting and reducing the liquid concentration for washing and reduces the diffusion and precipitation of P or B in poly by reducing the reaction temperature for washing. The achieved technical effect is shown in point 3 in FIG. 1, and the off-state current IOFF is not increased or not greatly increased while the on-state current ION is greatly increased. As shown in point 3 in FIG. 2, the drain-source current IDS is greatly increased while ensuring that the threshold voltage VT is not decreased or basically not decreased. As shown in point 3 in FIG. 3, the off-state current IOFF is not increased while ensuring that the threshold voltage VT is not decreased or basically not decreased. As shown in FIG. 9, the abscissa of “initial” represents a wafer that has not been optimized, “optimized” represents a wafer optimized by the manufacturing method of the present application, and ordinates are VT/IDS/IOFF from top to bottom. It can be seen that the VT of the NMOS does not change much before and after the optimization, the IDS is increased after the optimization by the manufacturing method of the present application, and the IOFF is decreased after the optimization by the manufacturing method of the present application, thereby increasing only the ION without increasing the VT/IOFF and increasing the on/off ratio of the device. Specifically, after cleaning the photoresist with the first solvent and before forming the semiconductor structure, as shown in FIG. 7, the manufacturing method further includes step S500: Form a second mask layer on the initial semiconductor structure, where the second mask layer has a second ion implantation window, and the second ion implantation window defines a position of a gate electrode of a second transistor; and perform a second ion implantation process to perform work function adjustment on the gate electrode of the second transistor through the second ion implantation window.

After the first mask layer is removed, a second mask material layer is deposited on the initial semiconductor structure. The second mask material layer is, for example, a photoresist material. Then, a patterned photoresist layer is formed by exposing and is developing, to form a second mask layer with a second ion implantation window. Ion implantation is performed on an exposed region of the polycrystalline silicon layer according to the second ion implantation window, for example, a P-type polycrystalline silicon layer is formed to serve as a gate electrode of a P-type transistor.

Specifically, after the second ion implantation process is performed and before the semiconductor structure is formed, as shown in FIG. 7, the manufacturing method further includes step S600: Remove the second mask layer by the first solvent.

The photoresist covering the second region is removed through cleaning with the first solvent to form a semiconductor structure. Specific process steps for cleaning the second mask layer may be the same as the above-mentioned process steps for cleaning the first mask layer, and the beneficial effects thereof are the same as those for cleaning the first mask layer, which are not repeated herein.

In an embodiment of the present disclosure, doped ions of the second ion implantation of the polycrystalline silicon layer are, for example, boron (B), and doping concentration is 1,013 atoms/cm² to 1,016 atoms/cm². A resistance per unit area of the polycrystalline silicon gate can be further adjusted by adjusting the doping concentration. Higher doping concentration indicates a lower resistance per unit area of the polycrystalline silicon gate.

In another embodiment of the present disclosure, doping ions of the second ion implantation of the polycrystalline silicon layer are, for example, at least one of phosphorus (P) or arsenic (As), and doping concentration may be 1,013 atoms/cm² to 1,016 atoms/cm². A resistance per unit area of the polycrystalline silicon gate can be further adjusted by adjusting the doping concentration. Higher doping concentration indicates a lower resistance per unit area of the polycrystalline silicon gate.

A type of implanted ions of the first ion implantation process is opposite to that of implanted ions of the second ion implantation process, and types of the first transistor and the second transistor are opposite to each other.

The embodiments of the present disclosure further provide a semiconductor structure, including a substrate and a polycrystalline silicon layer, where the is polycrystalline silicon layer is processed by the above-mentioned manufacturing method, to obtain the semiconductor structure.

The semiconductor structure further includes: an insulating oxide layer, where the insulating oxide layer is located between the substrate and the polycrystalline silicon layer. The insulating oxide layer is configured to implement electrical insulation between the polycrystalline silicon layer and the substrate. A material of the insulating oxide layer may be a material with a high dielectric constant, for example, silicon oxide, silicon oxynitride, silicon nitride, or hafnium oxide, or other suitable insulating substances, or a combination of the above materials. The insulating oxide layer is formed through, for example, physical vapor deposition, chemical vapor deposition, spin coating, or a combination thereof.

The semiconductor structure with a polycrystalline silicon gate provided in the present disclosure can be applied to, for example, a metal oxide semiconductor field effect transistor (MOSFET), an insulated gate bipolar transistor (IGBT), or a junction field effect transistor (JFET). The transistor including the semiconductor structure of the present disclosure can be applied to a semiconductor memory, which can be a computing memory (for example, a DRAM, an SRAM, a DDR3SDRAM, a DDR2SDRAM, or a DDRSDRAM), a consumer memory (for example, a DDR3SDRAM, a DDR2SDRAM, a DDRSDRAM, or an SDRSDRAM), a graphics memory (for example, a DDR3SDRAM, a GDDR3SDMRA, a GDDR4SDRAM, or a GDDR5SDRAM), a mobile memory, or the like. The beneficial effects thereof can be referred to the description of the semiconductor structure above, which are not repeated herein.

Those skilled in the art may easily figure out other implementations of the present disclosure after considering the specification and practicing the invention disclosed herein. This application is intended to cover any variations, purposes or adaptive changes of the present disclosure. Such variations, purposes or applicable changes follow the general principle of the present disclosure and include common knowledge or conventional technical means in the technical field which is not disclosed in the present disclosure. The specification and embodiments are merely considered as illustrative, and the real scope and spirit of the present disclosure are pointed out by the appended claims.

It should be noted that, the present disclosure is not limited to the precise structures that have been described above and shown in the accompanying drawings, and can be modified and changed in many ways without departing from the scope of the present disclosure. The scope of the present disclosure is defined by the appended claims.

1. A manufacturing method of a semiconductor structure, comprising:
providing an initial semiconductor structure, wherein the initial semiconductor structure comprises a substrate and a polycrystalline silicon layer;
forming a first mask layer on the initial semiconductor structure, wherein the first mask layer has a first ion implantation window, and the first ion implantation window defines a position of a gate electrode of a first transistor; and
performing a first ion implantation process to perform work function adjustment on the gate electrode of the first transistor through the first ion implantation window, to form a semiconductor structure.

2. The manufacturing method according to claim 1, wherein an insulating oxide layer is further formed on the semiconductor structure, and the insulating oxide layer is formed between the substrate and the polycrystalline silicon layer.

3. The manufacturing method according to claim 2, wherein after the performing a first ion implantation process, the manufacturing method further comprises:
removing the first mask layer by a first solvent, to form the semiconductor structure, wherein the first solvent is a hybrid aqueous solution of ammonia water and hydrogen peroxide.

4. The manufacturing method according to claim 3, wherein in the first solvent, a concentration of ammonia water falls within a first range, a concentration of hydrogen peroxide falls within a second range, a concentration of water falls within a third range, the third range is greater than the second range, and the second range is greater than the first range.

5. The manufacturing method according to claim 4, wherein in the first solvent, a ratio of the concentration of water to a sum of the concentration of ammonia water and the concentration of hydrogen peroxide is greater than 5:1.

6. The manufacturing method according to claim 3, wherein the removing the first mask layer by a first solvent comprises:
removing the first mask layer by both the first solvent and a second solvent, wherein the second solvent is a hybrid aqueous solution of sulfuric acid and hydrogen peroxide.

7. The manufacturing method according to claim 3, wherein the first mask layer is washed with the first solvent for multiple times.

8. The manufacturing method according to claim 3, wherein the first mask layer is washed with the first solvent at 25° C. to 30° C.

9. The manufacturing method according to claim 3, wherein the first mask layer is washed with the first solvent for 30 s to 150 s.

10. The manufacturing method according to claim 3, wherein after removing the first mask layer by the first solvent and before forming the semiconductor structure, the manufacturing method further comprises:
forming a second mask layer on the initial semiconductor structure, wherein the second mask layer has a second ion implantation window, and the second ion implantation window defines a position of a gate electrode of a second transistor; and
performing a second ion implantation process to perform work function adjustment on the gate electrode of the second transistor through the second ion implantation window; and
after the second ion implantation process, removing the second mask layer by the first solvent.

11. The manufacturing method according to claim 10, wherein types of the first transistor and the second transistor are opposite to each other, and a type of implanted ions corresponding to the first ion implantation process is opposite to a type of implanted ions of the second ion implantation process.

12. The manufacturing method according to claim 11, wherein the first transistor is a P-type transistor, the second transistor is an N-type transistor, ions of the first ion implantation comprise B ions, and ions of the second ion implantation comprise AS/P ions.

13. The manufacturing method according to claim 11, wherein the first transistor is an N-type transistor, the second transistor is a P-type transistor, ions of the first ion implantation comprise AS/P ions, and ions of the second ion implantation comprise B ions.

14. A semiconductor structure, comprising a substrate and a polycrystalline silicon layer, wherein the polycrystalline silicon layer is processed by the manufacturing method according to claim 1, to obtain the semiconductor structure.

15. The semiconductor structure according to claim 14, the semiconductor structure further comprises:
an insulating oxide layer, located between the substrate and the polycrystalline silicon layer.
